(19) United States
(12) Patent Application Publication
(10) Pub. No.: US 2013/0223022 A1
(43) Pub. Date: Aug. 29, 2013

(54) SLIDE TYPE MOBILE DEVICE

(71) Applicant: Pantech Co., Ltd., (US)

(72) Inventor: Gi Dae KIM, Seoul (KR)

(73) Assignee: PANTECH CO., LTD., Seoul (KR)

(21) Appl. No.: 13/674,557

(22) Filed: Nov. 12, 2012

(30) Foreign Application Priority Data
Feb. 29, 2012 (KR) 10-2012-0021115

(51) Int. Cl. H05K 7/00; H05K 5/02

(52) U.S. Cl. CPC H05K 7/00; H05K 5/0226
USPC 361/749; 312/334.1

(57) ABSTRACT

A slide type mobile device includes a first body and a second body connected by a hinge member to provide a sliding movement of the first body with respect to the second body; and a protrusion part disposed on one of the first body and the second body to extend toward the other of the first body and the second body

### CROSS-REFERENCE TO RELATED APPLICATION

This application claims priority from and the benefit under 35 U.S.C. §119(a) of Korean Patent Application No. 10-2012-0021115, filed on Feb. 29, 2012, the entire disclosure of which is incorporated herein by reference for all purposes.

### BACKGROUND

1. Field

The following description relates to a slide type mobile device, and more particularly, to a slide type mobile device capable of reducing a likelihood of incurring damage of a flexible component, such as a flexible printed circuit board, inside a mobile device having an opening and closing structure.

2. Discussion of the Background

A mobile device with communication capability has come into wide use with advancements in the mobile communication industry. The operations and/or capabilities of the mobile device have improved along with the advancement in the industry of the mobile device.

Mobile devices may include a slide type mobile device in which a display screen of disposed on a top portion of the mobile device and/or a keypad disposed on a lower portion of the mobile device are separated from each other.

FIG. 1A and FIG. 1B are diagrams illustrating a slide type mobile device 1 according to the related art. Referring to FIG. 1A, the slide type mobile device 1 includes a first body 100 equipped with a display part 150 and a second body 200 equipped with an input unit 250, such as a keypad used to provide data input.

Referring to FIG. 1A and FIG. 1B, a first hinge 310 and a second hinge 330 are respectively installed between the first body 100 and the second body 200 to enable a sliding movement of the first body 100 with respect to the second body 200 or vice-versa. The first body 100 and the second body 200 may be movable between a closed state shown in FIG. 1A in which the input unit 250 is concealed by the first body 100, and an opened state of FIG. 1B in which the input unit 250 is exposed to the outside to be accessible to a user in accordance with an interaction of the first hinge 310 and the second hinge 330. The first body 100 and the second body 200 are electrically connected to each other through a flexible printed circuit board 410 so that data communication may be executed therebetween. The flexible printed circuit board 410 is disposed between the first body 100 and the second body 200 in a bent state.

A gap is formed between the first body 100 and the second body 200 to enable the sliding movement of the first body 100 and the second body 200. Accordingly, a foreign material including, without limitation, a card, such as a plastic card, or a sheet-like material C, such as paper, may be inserted into the gap formed between the first body 100 and the second body 200 in an opened state shown in FIG. 1B or a closed state shown in FIG. 1A. Accordingly, when the foreign material is inserted into the gap and comes in contact with the flexible printed circuit board 410, the flexible printed circuit board 410 may become damaged or torn. Thus, useable life or durability of the flexible printed circuit board 410 may be shortened or reduced, and the mobile device may not be operated.

Accordingly, there may be an increase in demand for a mobile device structure capable of reducing a likelihood of receiving damage to a flexible component, such as a flexible printed circuit board, in a restricted space inside of the mobile device.

### SUMMARY

Exemplary embodiments of the present invention provide a slide type mobile device.

Additional features of the invention will be set forth in the description which follows, and in part will be apparent from the description, or may be learned by practice of the invention.

Exemplary embodiments of the present invention provide a mobile device including a first body and a second body connected by a hinge member to provide a sliding movement of the first body with respect to the second body; and a protrusion part disposed on one of the first body and the second body to extend toward the other of the first body and the second body.

Exemplary embodiments of the present invention provide a mobile device including a first body and a second body connected by a hinge member to provide a sliding movement; a projecting part disposed on the first body to extend towards the second body; and a protrusion part disposed on the second body to extend towards the first body, in which the protrusion part and the projecting part are arranged to form a stopper structure when the first body is in an opened state with respect to the second body.

Exemplary embodiments of the present invention provide a slide type mobile device including a first body and a second body connected by a hinge member to move in a sliding motion with respect to one another; a flexible printed circuit board disposed to extend between the first body and the second body; a first protrusion part disposed at a first side on a surface of the second body within a reference proximity of the flexible printed circuit board; and a second protrusion part disposed at a second side on the surface of the second body within a reference proximity of the flexible printed circuit board.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A is a cross-sectional view illustrating a slide type mobile device according to the related art in a closed state.

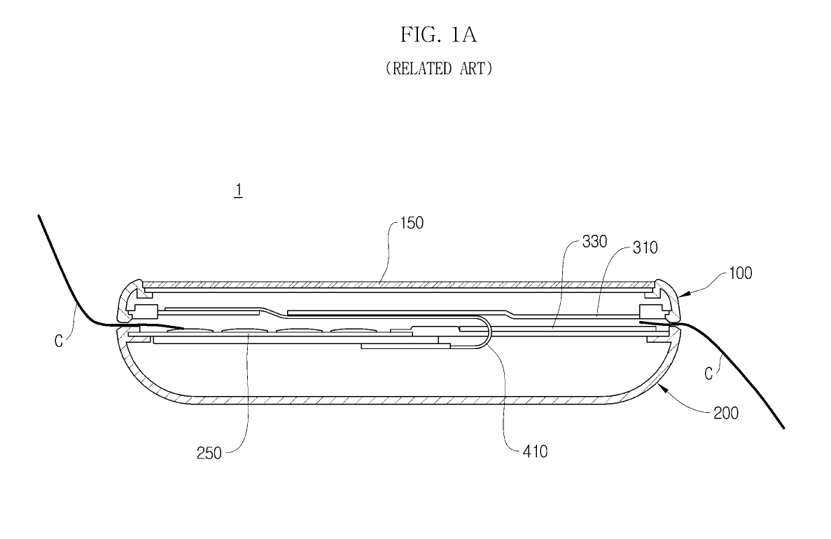

FIG. 1B is a cross-sectional view illustrating a slide type mobile device according to the related art in an opened state.

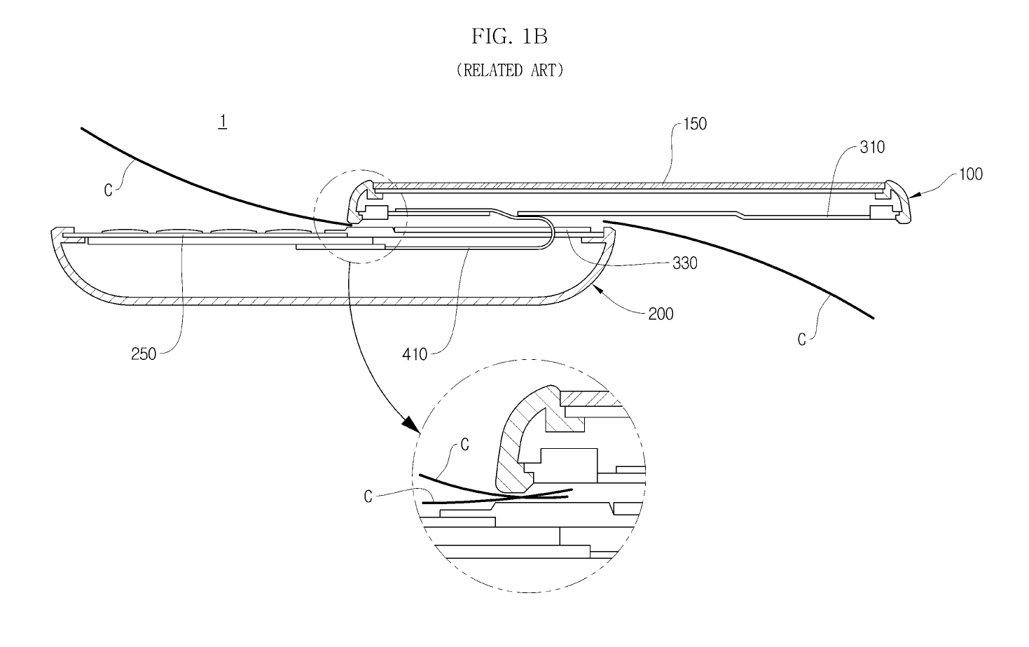

FIG. 2A provides various views illustrating a slide type mobile device in a closed state according to an exemplary embodiment of the present invention.

FIG. 2B provides a side cross-sectional view illustrating a slide type mobile device in a closed state according to an exemplary embodiment of the present invention.

FIG. 2C provides a side cross-sectional view illustrating a slide type mobile device in an opened state according to an exemplary embodiment of the present invention.

FIG. 3 is a diagram illustrating a hinge member of a slide type mobile device according to an exemplary embodiment of the present invention.

FIG. 4A is a schematic diagram illustrating a slide type mobile device in a closed state according to an exemplary embodiment of the present invention.

FIG. 4B is a schematic diagram illustrating a part of a slide type mobile device in an opened state according to an exemplary embodiment of the present invention.

FIG. 5 is a schematic plan view illustrating a state where a card is inserted into a slide type mobile device according to an exemplary embodiment of the present invention.

FIG. 6 is a schematic diagram illustrating a slide type mobile device in an opened state according to an exemplary embodiment of the present invention.

FIG. 7 is a schematic diagram illustrating a slide type mobile device in an opened state according to an exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. It will be understood that when an element is referred to as being “on” or “connected to” or “coupled to” another element, it can be directly on, directly connected to, or directly coupled to the other element, or intervening elements may be present. In contrast, if an element is referred to as being “directly on” or “directly connected to” or “directly coupled to” another element, no intervening elements are present. Further, it will be understood that for the purposes of this disclosure, “at least one of X, Y, and Z” can be construed as X only, Y only, Z only, or any combination of two or more items X, Y, and Z (e.g., XYZ, XZ, XYY, YZ, ZZ). Throughout the drawings and the detailed description, unless otherwise described, the same drawing reference numerals are understood to refer to the same elements, features, and structures. The relative size and depiction of these elements may be exaggerated for clarity.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Although some features may be described with respect to individual exemplary embodiments, aspects need not be limited thereto such that features from one or more exemplary embodiments may be combinable with other features from one or more exemplary embodiments.

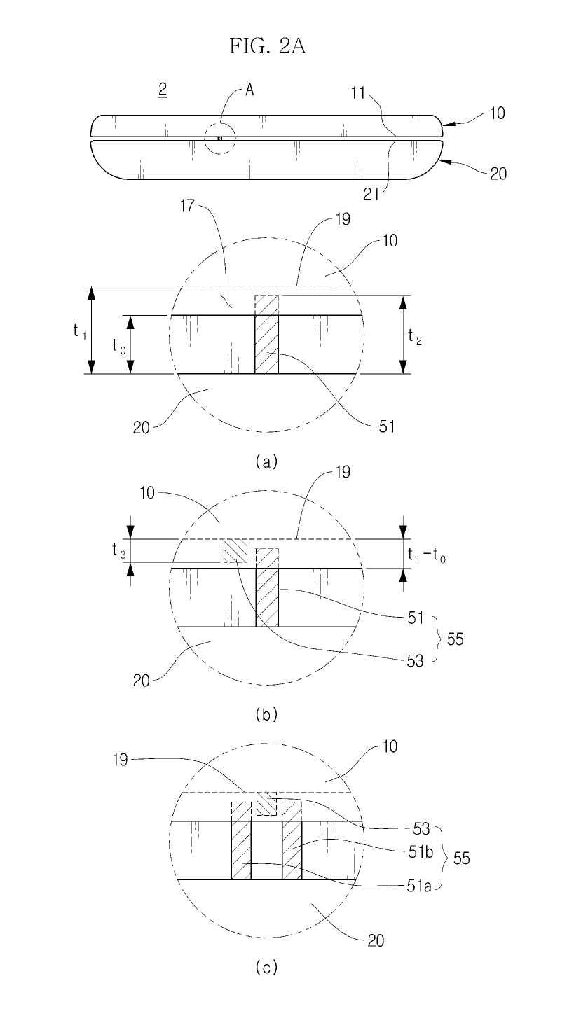

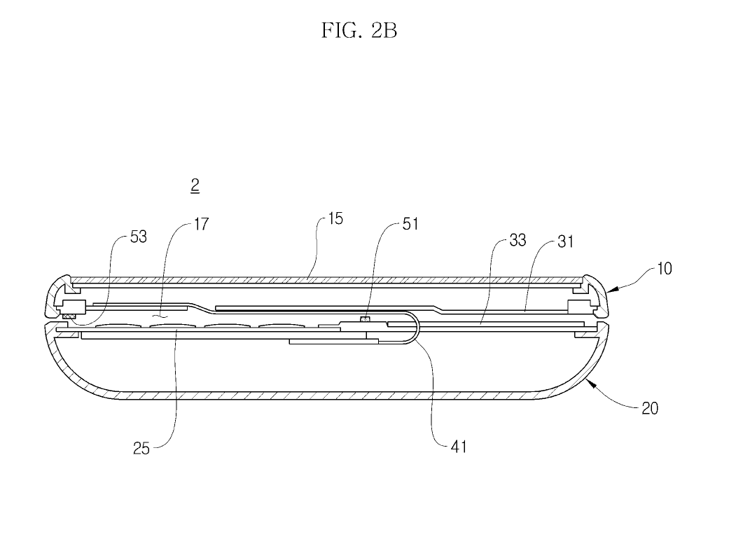

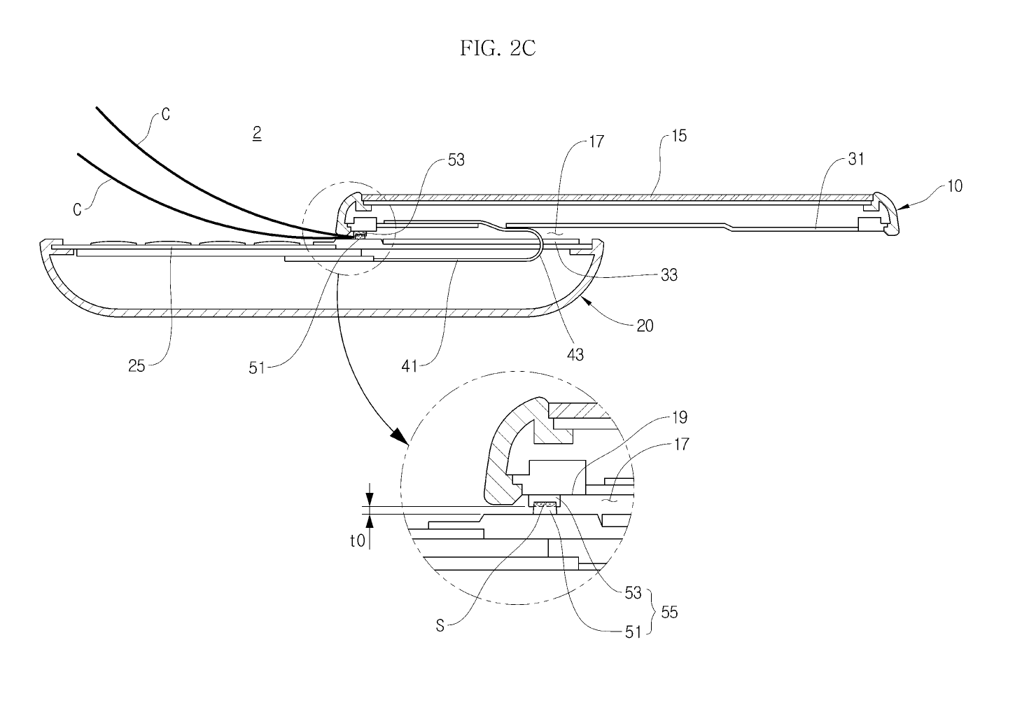

FIG. 2A provides various views illustrating a slide type mobile device in a closed state according to an exemplary embodiment of the present invention. More specifically, FIG. 2A illustrates a front view of the slide type mobile device and various enlarged views illustrating region A of a slide type mobile device. FIG. 2B provides a side cross-sectional view illustrating a slide type mobile device in a closed state according to an exemplary embodiment of the present invention. FIG. 2C provides a side cross-sectional view illustrating a slide type mobile device in an opened state according to an exemplary embodiment of the present invention.

A surface of the mobile device viewed in a direction parallel to the slide direction of the mobile device may be referred to as a front surface or a rear surface. Further, a surface of the mobile device when seen in a direction perpendicular to the slide direction of the mobile device may be referred to as a side surface, such as, a left surface and a right surface. Accordingly, FIG. 2A illustrates a diagram of the mobile device seen from the front side, and FIG. 2B and FIG. 2C provide cross-sectional views of the device seen from a side surface of the mobile device in the closed state and the opened state, respectively.

Referring to FIG. 2A, a slide type mobile device 2 includes a first body 10 and a second body 20, which is coupled or connected to the first body 10 so as to move in a sliding motion. In an example, the first body 10 and the second body 20 may refer to either a top half or a bottom half of the mobile device and is not limited to a particular designation. Further, a sliding direction may refer to a direction to which the first body 10 moves in a direction of an applied force with respect to the second body 20. More specifically, if a user pushes on a surface of the first body 10 in a right direction, the first body 10 may move or slide in the right direction or a sliding direction with respect to the second body 20. Similarly, the sliding direction may also refer to a direction to which the second body 20 moves in a direction of an applied force with respect to the first body 10.

The first body 10 may be provided with an accommodation region 17, which may be disposed between the first body 10 and the second body 20 to form a predetermined space. More particularly, the accommodation region 17 may be formed or disposed in a portion of first surface 11 of the first body 10, which faces a second surface 21 of the second body 20. The accommodation region 17 may refer to a gap or space provided between the first body 10 and the second body 20, i.e., between the first surface 11 of the first body 10 and the second surface 21 of the second body 20.

The accommodation region 17 may be formed or disposed as an integrated part of the second body 20 or a separate component to be coupled to the second body 20. Further, the accommodation region 17 may form a sliding space between the first body 10 and the second body 20. However, aspects of the invention are not limited thereto, such that the accommodation region 17 may be formed or disposed on the first body 10 or portions of the accommodation region 17 may be formed or disposed on both of the first body 10 and the second body 20. The accommodation region 17 may be a cavity or space, which may be separately formed or disposed to accommodate a protrusion part or a projecting part disposed therein.

The accommodation region 17 may be formed or disposed along the sliding direction of the first body 10. A protrusion part 51, which may protrude toward the first body 10 within the accommodation region 17 to prevent or reduce a likelihood of an external foreign material from intruding into the accommodation region 17. The protrusion part 51 may be formed or disposed on the second surface 21 of the second body 20 and within the accommodation region 17 to face the first surface 11 of the first body 10.

Further, since the protrusion part 51 is formed or disposed in the accommodation region 17 between the first body 10 and the second body 20 to protrude toward a first surface 11 of first body 10, it may be possible to reduce the likelihood of intrusion of foreign materials, such as an external thin sheet-like material. The sheet-like foreign material may include, without limitation, a card, such as a plastic card, or a thin sheet-like external material, such as a paper card or a name card. The sheet-like foreign material may be a material, which may be capable of intruding towards a flexible printed circuit board through a gap between the first body 10 and the second body 20 may be blocked by the protrusion part 51 disposed at an interior portion between the first body 10 and the second body 20. Here, although the protrusion part 51 is disposed on a top surface or second surface 21 of the second body 20 and extended towards a bottom surface or first surface 11 of the first body 10, aspects of the invention are not limited thereto. The protrusion part 51 may be disposed on the bottom surface and extended towards the top surface of the second body 20.

Referring to FIG. 2A, (a) of FIG. 2A is an enlarged view of region A.

In (a) of FIG. 2A, since the protrusion part 51 extends to an internal region of the accommodation region 17 so that the height t₂ of the protrusion part 51 is larger than the gap tₒ between a portion of the first body 10 and a portion of the second body 20, at least a portion of the gap formed or disposed between the first body 10 and the second body 20 may be blocked by the protrusion part 51 to obstruct entry into the accommodation region 17. Accordingly, a likelihood of an external sheet-like foreign material intruding into the accommodation region 17 beyond the protrusion part 51 may be reduced when the mobile device is in the closed state or the opened state.

Further, although one protrusion part 51 is depicted, the mobile device may accommodate multiple protrusion parts 51. Further, location of the protrusion part 51 may not be limited to an interior portion of the accommodation region 17, such that the protrusion part 51 may be located towards an edge of the accommodation region 17. More specifically, the protrusion part 51 may be located within a reference proximity to an end portion of one of the first body 10 or the second body 20, such as a top portion of a terminal. In addition, the protrusion part 51 may be disposed on a portion the first surface 11 of the first body 10, a portion of the second surface 21 of the second body 20, or both on the first surface 11 of the first body 10 and the second surface 21 of the second body 20.

When a protrusion part is formed or disposed in a region, which may not correspond to the accommodation region 17, more specifically, when the protrusion part is formed or disposed in a region of the second body 20 that may not correspond to the accommodation region 17, damage may be caused by the protrusion part during a sliding movement. Further, the gap between the first body 10 and the second body 20 may be narrow below a reference threshold, such that when a user slides the mobile device 2 to open or close the mobile device 2, the first body 10 and the second body 20 may move in a pressurized state. Accordingly, the protrusion part 51 may come into contact with a bottom portion of the first body 10, which may contact or scratch the bottom portion of the first body 10 to prevent or restrict a sliding movement. The protrusion 51 may be damaged by the friction generated against the first body 10.

Accordingly, the protrusion part 51 may be formed or disposed to be positioned inside of the accommodation region 17 to be spaced apart from a first portion 19 of the accommodation region 17 by a predetermined distance so that the sliding movement is not disturbed.

More particularly, the height of the protrusion part 51, height t₂, may be smaller than a first gap t₁, which may be measured from the first portion 19 of the accommodation region 17 to a bottom end of the protrusion part 51 disposed in the second body 20. For example, a second gap t₁-t₂, which may correspond to a distance between the first portion 19 of the accommodation region 17 and a top surface of the protrusion part 51, may range from 0.1 millimeter (mm) to 0.2 mm, but is not limited thereto.

When the second gap is smaller than 0.1 mm, the sliding movement may be disturbed. When the second gap is larger than or equal to 0.2 mm, the gap between the first body 10 and the second body 20 is widened, such that the size of the product changes, which may allow the foreign material to intrude into a space between a protrusion part and a bottom portion of an accommodation region.

Referring to FIG. 2A again, (b) of FIG. 2A is an enlarged view of the region A. Referring to (b) of FIG. 2A, a third depth t₁-t₀, which may correspond to a height of the accommodation region 17, may be a depressed space with a distance ranging from 0.4 mm to 0.7 mm as an example, but is not limited thereto. For example, the length of the depressed space may have a distance of about 0.6 mm.

A projecting part 53 may be formed or disposed on the first surface 11 of the first body 10 at the first portion 19 of the accommodation region 17. More specifically, the projecting part 53 may be disposed within a reference proximity of a first end portion of one of the first body 10. However, aspects of the invention are not limited thereto, such that the projecting part 53 may be disposed or formed on the first end portion of the second body 20. The projecting part 53 may extend from the first surface 11 of the first body 10 towards the second surface 21 of the second body 20. The protrusion part 51 and the projecting part 53 may be arranged in parallel inside the accommodation region 17, but aspects are not limited thereto. For example, the protrusion part 51 and the projecting part 53 may be disposed at different angles. Further, the protrusion part 51 and the projecting part 53 may be formed or disposed to have an overlap area during an opened state. More specifically, the protrusion part 51 and the projecting part 53 may overlap with each other to form a stopper structure 55, which may block a gap between the first body 10 and the second body 20 to obstruct passage of foreign materials through the gap.

The projecting part 53 may be disposed in parallel to the protrusion part 51 inside the accommodation region 17 in the opened state, the closed state, or the sliding state to form an overlap area therebetween.

The gap of a reference distance, for example, 0.15 mm may be formed or disposed between the protrusion part 51 and the first portion 19 of the accommodation region 17. Since the protrusion part 51 and the projecting part 53 may be perpendicularly connected, arranged, or formed with respect to each other when seen from the side view to form the stopper structure 55, the gap or the space between the first portion 19 of the accommodation region 17 and the protrusion part 51 may be also blocked or obstructed. Accordingly, the gap between the first body 10 and the second body 20 may be blocked as a whole.

More particularly, a height t₃ of the projecting part 53 may be smaller than a third depth, or a distance of t₁-t₀ of the accommodation region 17. Accordingly, the projecting part 53 may be formed or disposed to be concealed when seen from the outside. However, aspects of the invention are not limited thereto, such that a height of the projecting part 53 may be the same height, or greater than the third depth in the accommodation region 17.

However, aspects of the invention are not limited thereto, such that the height of the projecting part 53 may be the same height, or greater than the third depth in the accommodation region 17. More specifically, the projecting part 53 may be formed or disposed to be exposed to the outside of the accommodation region 17. Further, the projecting part 53 may be formed or disposed to be apart from the second body 20 by a predetermined gap.

Furthermore, when the projecting part 53 is formed or disposed to be exposed to the outside of the accommodation region 17, the protrusion part 51 may not extend to contact the accommodation region 17 as long as the protrusion part 51 and the projecting part 53 have an overlap area.

Referring to FIG. 2A, (c) of FIG. 2A is an enlarged view of region A.

In (c) of FIG. 2A, a first protrusion part 51a and a second protrusion part 51b may be disposed on the second body 20 to be away from each other by a predetermined gap, and a projecting part 53 may be formed or disposed between the first protrusion part 51a and the second protrusion part 51b in the accommodation region 17 so that the first protrusion part 51a and the second protrusion part 51b may be arranged in parallel. The projecting part 53 is disposed on the first body 10. The first protrusion part 51a and the second protrusion part 51b and the projecting part 53 may be arranged in parallel so as to form the stopper structure 55. However, aspects of the invention are not limited thereto, such that at least one of the protrusion parts and the projecting part may be arranged at different angles or shapes.

In (c) of FIG. 2A, two protrusion parts and one projecting part are illustrated, but aspects of the invention are not limited thereto. For example, one protrusion part and two projecting parts may be formed or disposed in the accommodation region 17, and a number of combinations of the projecting part and the protrusion parts may be arranged in parallel to form or provide a stopper structure.

Hereinafter, an exemplary embodiment in which the protrusion part 51 and the projecting part 53 overlap or contact each other to form a stopper structure 55 with respect to (c) of FIG. 2A will be described.

FIG. 2B provides a side cross-sectional view illustrating a slide type mobile device in a closed state according to an exemplary embodiment of the present invention. FIG. 2C provides a cross-sectional view illustrating a slide type mobile device in an opened state according to an exemplary embodiment of the present invention.

More specifically, the first body 10 may include a display part 15, and may be an upper body, which moves in a sliding motion with respect to the second body 20, which may the lower body.

The second body 20 may include an input unit 25 equipped with a keypad. The keypad may include, without limitation, a general numerical keypad, a QWERTY keypad, and the like may be used.

Examples of the slide type mobile device include a mobile device, for example, a slide type mobile communication device in which a second body equipped with a keypad moves in a sliding motion with respect to a first body in the lengthwise direction or a sliding direction. A sliding direction may refer to a direction to which the first body 10 moves in a direction of an applied force with respect to the second body 20. More specifically, if a user pushes on a surface of the first body 10 in a right direction, the first body 10 may move or slide in the right direction or a sliding direction with respect to the second body 20. Similarly, the sliding direction may also refer to a direction to which the second body 20 moves in a direction of an applied force with respect to the first body 10.

Examples of the slide type mobile device also includes a mobile device, for example, a slide type mobile communication device equipped with a QWERTY keypad in which a second body moves in a sliding motion with respect to a first body in the widthwise direction. The lengthwise direction of the mobile device may refer to a direction corresponding to a side of the mobile device that may be longer in length. The widthwise direction may refer to a side of the mobile device that may be shorter in length. However, aspects of the invention are not limited thereto, such that the first body or the second body may slide at an angle with respect to each other, or slide in a rotating manner with respect to each other.

However, aspects of the invention are not limited thereto. For example, the second body 20 may include the display part, the first body 10 may include the input unit, the second body 20 may be the upper body, and the first body 10 may be the lower body.

Furthermore, a sliding member, which may provide and/or support the sliding movement, may be installed between the first body 10 and the second body 20. FIG. 2B and FIG. 2C illustrate a hinge member including a first hinge 31 and a second hinge 33 adopted as a sliding member. However, aspects of the invention are not limited thereto. For example, various types of mechanisms may be adopted to provide the sliding movement, such as a type of a Pogo® pin, which may support the sliding movement using an elastic force, or a type in which one of a first body and a second body facing each other may be provided with a guide groove along the slide direction and the other surface is provided with a projection part coupled to the guide groove so that the projection part may move along the guide groove to support the sliding movement. Hereinafter, an exemplary embodiment a mobile device in which the hinge member is used as the sliding member will be described.

The first body 10 and the second body 20 may have a predetermined stroke or motion by being connected to each other through the hinge member including the first hinge 31 coupled to the first body 10 and the second hinge 33 coupled to the second body 20. The first body 10 and the second body 20 may be configured to slide from an opened state to a closed state, or from the closed state to the opened state. The second hinge 33 may be coupled to the first hinge 31 to support a sliding motion, and the second body 20 as the lower body may be configured to slide on the first body 10 as the upper body.

A predetermined gap may be formed or disposed between the first body 10 and the second body 20 so that the first body 10 and the second body 10 may slide by using the first hinge 31 and the second hinge 33 attached thereto. The gap t₀ between the first body 10 and the second body 20 may be formed or disposed to have a range of 0.2 mm to 0.4 mm, but is not limited thereto. Due at least in part to the gap, the foreign material may be inserted from the outside.

The accommodation region 17, which may provide a space between the first body 10 and the second body 20, may be formed or disposed for various purposes. For example, the accommodation region 17 may be a recessed portion that may accommodate sliding movement with reduced likelihood of incurring friction and/or protect various components mounted therein. Further, at least one of the protrusion part 51 and the projecting part 53 may provide protection from intrusion of the external foreign material that may enter into the accommodation region 17.

The accommodation region 17 may be formed or disposed in the first body 10 along a sliding direction so that the first body 10 and the second body 20 may accommodate the protrusion part 51 in the opened state, the closed state, or the sliding state. Accordingly, the protrusion part 51 may move within the space inside the accommodation region 17 when the first body 10 and the second body 20 are in the closed state, the sliding state, and the opened state, so that a likelihood of the intrusion of the external foreign material may be prevented or reduced. However, aspects of the invention are not limited thereto, such that the accommodation region 17 may be formed or disposed in the first body 10, the second body 20, or in both first body 10 and the second body 20.

A flexible printed circuit board 41 is disposed to extend between the first body 10 and the second body 20. Further, portions of the flexible printed circuit board 41 may be connected to the first body 10 and the second body 20 and may include a C-shaped curved part 43, which may be formed between the first body 10 and the second body 20. The flexible printed circuit board 41 may electrically connect the first body 10 to the second body 20. Although a single C-shaped curved part is illustrated, aspects of the invention are not limited thereto, such that the slide type mobile device may include multiple C-shaped curved parts so that the flexible printed circuit board 41 may be in an S-shape or other shapes. Further, additional protrusion parts may be included in the slide type mobile device to protect the additional C-shaped curved parts.

A predetermined space may be maintained between the first body 10 and the second body 20 so as to support the sliding path or movement of the flexible printed circuit board 41 while accommodating the flexible printed circuit board 41 disposed therein.

Referring to FIG. 2B and FIG. 2C, the accommodation region 17 may refer to a space or cavity which is provided to support the sliding path or movement of the flexible printed circuit board 41. When the protrusion part 51 is disposed in the accommodation region 17 to support the sliding path or movement of the flexible printed circuit board 41 in the first body 10, the flexible printed circuit board 41 may be protected from sheet-like foreign material, which may intrude from outside. The width of the accommodation region 17 (i.e., the width when viewing the mobile device from the front side) may be larger than or equal to a combined width of the flexible printed circuit board 41 and the protrusion part 51. Further, when the projecting part 53 is contacted with or moved adjacent to the protrusion part 51, the width of the accommodation region 17 may be set to a width in which the projecting part 53 may also be accommodated. Accordingly, the width of the accommodation region 17 may be larger than or equal to a combined width of the flexible printed circuit board 41, the protrusion part 51, and the projecting part 53.

The sliding path of the flexible printed circuit board 41 may refer to a path of movement of the flexible printed circuit board 41 disposed between the first body 10 and the second body 20. More specifically, the sliding path or movement of the flexible printed circuit board 41 may correspond to a region accommodating a part of the flexible printed circuit board 41 disposed between the first body 10 and the second body 20 from an existing portion in the first body 10 to an entering portion in the second body 20. However, the sliding path is not limited to a sliding movement may accommodate various movements of the flexible printed circuit board 41.

The protrusion part 51 may be formed or disposed towards a rear portion of the second body 20 in the sliding or moving direction. Further, the protrusion part 51 may be disposed to face a concave portion of the flexible printed circuit board 41. Accordingly, when the second body 20 slides out to move into an opened state, the protrusion part 51 may be concealed by the first body 10 not to be exposed to the outside. Furthermore, the projecting part 53 may be formed or disposed towards a front portion or a front end portion of the accommodation region 17 of the first body 10 in the sliding direction. However, although not illustrated, the projecting part 53 may also be formed or disposed towards a second end portion of the accommodation region 17. More particularly, when a keypad is installed or disposed on the second surface 20 of the second body 20, the protrusion part 51 may be positioned towards rear of the keypad, and the projecting part 53 may be aligned together with the protrusion part 51 in a horizontal direction while the mobile device 2 is in the opened state. Accordingly, when the second body 20 moves in a sliding direction to an opened state, the protrusion part 51 and the projecting part 53 may be arranged to provide a stopper structure 55.

The projecting part 53 may perform a sliding movement with respect to the first body 10. When a height of the projecting part 53 is smaller than the height of the accommodation region 17, the projecting part 53 may be formed or disposed to be concealed inside the accommodation region 17.

When the projecting part 53 and the protrusion part 51 are arranged in parallel to have an overlap area, the projecting part 53 and the protrusion part 51 may be arranged to provide or form the stopper structure 55, which may provide a blockade or an obstruction in the gap formed between the first body 10 and the second body 20.

The stopper structure 55 may be formed or provided by the protrusion part 51 and the projecting part 53 being arranged in parallel in the opened state, but is not limited thereto. For example, the protrusion part 51 and the projecting part 53 may be arranged at various angles but overlap to provide an obstruction in the gap formed between the first body 10 and the second body 20. The stopper structure 55 may be formed or arranged when the first body 10 and the second body 20 are in any one of the opened state, the closed state, and the sliding state. Since the projecting part 53 may be positioned inside the accommodation region 17, the stopper structure 55 may be provided in a desired state without scratching the casing of the mobile device 2 or disturbing the sliding movement.

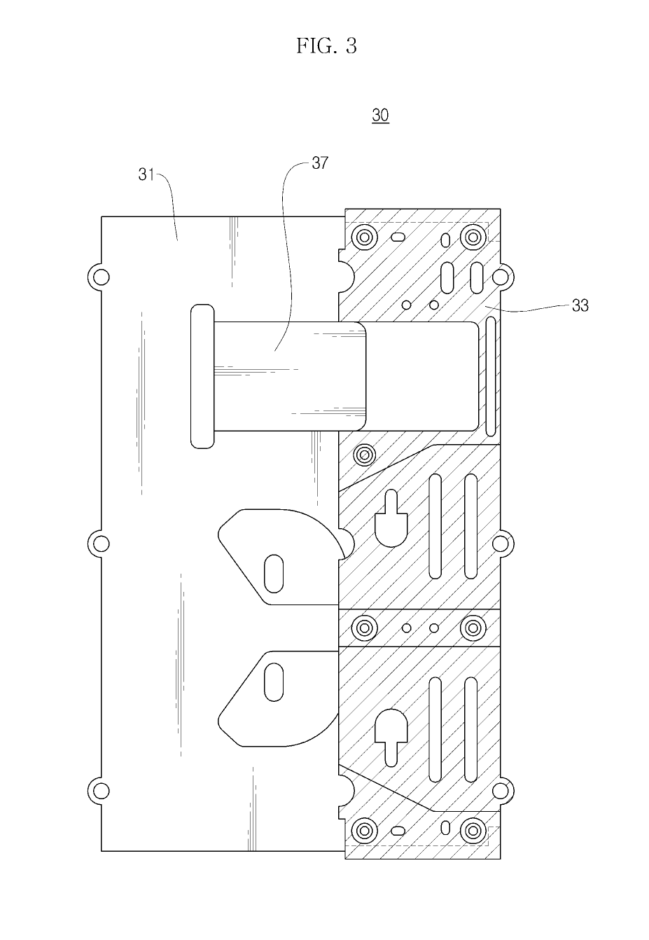

FIG. 3 is a diagram illustrating a hinge member of a slide type mobile device according to an exemplary embodiment of the present invention.

FIG. 3 is a diagram illustrating a hinge member 30, which may be obtained by coupling the first hinge 31 and the second hinge 33 when seen with respect to the second body 20. The hinge member 30 includes the first hinge 31 and the second hinge 33. The first hinge 31 may be attached to the first body 10, and the second hinge 33 may be attached to the second body 20. However, aspects of the invention are not limited thereto, such that the first hinge 31 may be attached to the second body 20 and the second hinge 33 may be attached to the first body 10.

The first hinge 31 and/or the second hinge 33 may realize the opened state or the closed state based on the sliding movement. The first hinge 31 and the second hinge 33 may be disposed or arranged to slide in a linear direction, but is not limited thereto. The first hinge 31 and the second hinge 33 may be disposed or arranged to slide about the rotary axis, such that the first hinge 31 and the second hinge 33 realize the closed state and the opened state.

Referring to FIG. 3, the first hinge 31 of the first body 10 may be provided with an accommodation region 37. An opening to the accommodation region 17 may be formed or disposed in the first body 10, more specifically, in the first hinge 31, but is not limited thereto.

More specifically, the accommodation region 37 may be similar to the accommodation region 17 shown in FIG. 2B and FIG. 2C, such that the accommodation region 37 may be provided to support the moving path of a flexible printed circuit board. More specifically, the accommodation region 37 may be a recessed portion or region, which may allow movement of the flexible printed circuit board. However, aspects of the invention are not limited thereto, and the hinge member 30 may be formed or disposed as a guide rail between the first body and the second body, and may support a sliding movement using a spring pin or the like.

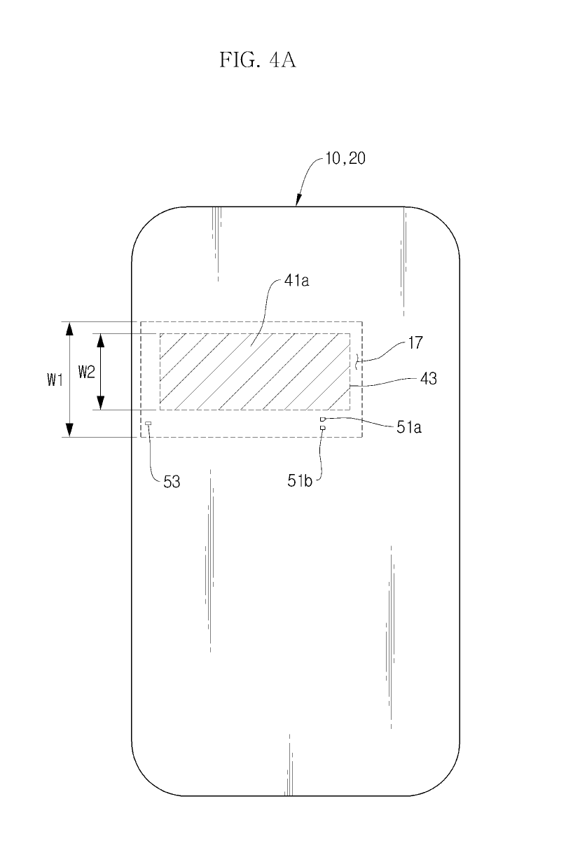

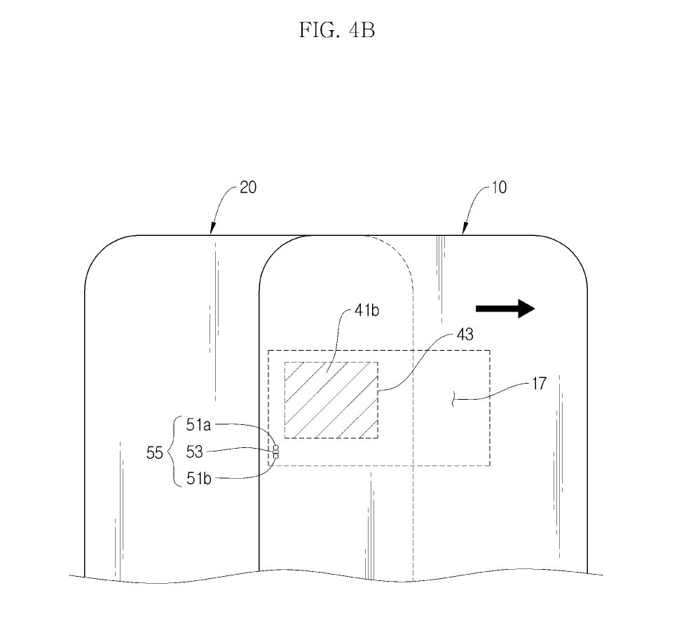

FIG. 4A is a schematic diagram illustrating a slide type mobile device in a closed state according to an exemplary embodiment of the present invention. FIG. 4B is a schematic diagram illustrating a part of a slide type mobile device in an opened state according to an exemplary embodiment of the present invention.

FIG. 4A and FIG. 4B are schematic diagrams illustrating a slide type mobile device illustrating positions of the accommodation region 17, a first flexible printed circuit part 41a and a second flexible printed circuit part 41b of the flexible printed circuit board, a first protrusion part 51a, a second protrusion part 51b, and the projecting part 53 when the first body 10 and the second body 20 are in the closed state, as shown in FIG. 4A, and the opened state, as shown in FIG. 4B.

Referring to FIG. 4A, when the first body 10 and the second body 20 are integrated with each other in the closed state, the first protrusion part 51a and the second protrusion part 51b may be formed or disposed in the second body 20 to be apart from each other by a predetermined gap. Since the C-shaped curved part 43 is disposed between the first body 10 and the second body 20, a sheet-like foreign material, such as paper or a card may have difficulty in reaching the C-shaped curved part 43.

Referring to FIG. 4B, the first body 10 may slide in a direction indicated by the arrow to be positioned in the opened state. During the sliding movement towards the opened state, the flexible printed circuit board attached to the first body 10 and the C-shaped curved part 43 may move along with the first body 10. Further, the flexible printed circuit board attached to the first body 10 and the C-shaped curved part 43 may move simultaneously with the first body 10. In the opened state of a conventional slide type mobile device, the concave part of the C-shaped curved part 43 may approach an edge of the first body 10, such that even when a foreign material, such as a sheet-like foreign material is slightly inserted, the sheet-like foreign material may reach the C-shaped curved part 43, so that the flexible printed circuit board may be damaged.

However, according to exemplary embodiments of the present invention, the first protrusion part 51a and the second protrusion part 51b are formed or disposed in the second body 20, and arranged to be aligned with the projecting part 53 in the opened state. More specifically, since the first protrusion part 51a and the second protrusion part 51b are formed or disposed within or adjacent to the sliding path or movement of the printed circuit board in a direction a foreign material, such as a card, may be intruded, the path of intrusion by the foreign material or card may be blocked or obstructed. Accordingly, a likelihood of the intrusion by the external foreign material in a gap formed or disposed in the mobile device may be prevented or reduced.

FIG. 4A and FIG. 4B schematically illustrate the stopper structure 55, which may be formed or disposed by arranging the first protrusion part 51a, the second protrusion part 51b, and the projecting part 53.

Referring to FIG. 4A, in the closed state, the projecting part 53 is disposed apart from the first protrusion part 51a and the second protrusion part 51b by a reference distance. The projecting part 53 may be concealed and disposed at a first surface 11 of the first body 10, and the first protrusion part 51a and the second protrusion part 51b are arranged at a first region or a left region of the mobile device, which may correspond to an insertion direction of a foreign material, such as the sheet-like foreign material. More specifically, a front edge or a first edge of the C-shaped curved part 43 may correspond to an entrance of the foreign material to be inserted. Further, the C-shaped curved part 43 may be positioned inside or adjacent to the sliding space or path of the flexible printed circuit board, thereby preventing or reducing a likelihood of the foreign material reaching the C-shaped curved part 43.

Referring to FIG. 4B, in the opened state, the projecting part 53 is aligned with the first protrusion part 51a and the second protrusion part 51b in an engaged state to form the stopper structure 55.

The width W1 of the accommodation region 17, which may be formed or disposed in the hinge member or the first body 10 may be larger than or equal to the width W2 of the flexible printed circuit board. More particularly, the width W1 of the accommodation region 17 may be larger than the width W2 of the flexible printed circuit board by a combined width of at least one of the projecting part 53, the first protrusion part 51a, and the second protrusion part 51b. More particularly, since the projecting part 53, the first protrusion part 51a, and the second protrusion part 51b are disposed adjacent to the sliding space of the flexible printed circuit board, the width W1 of the accommodation region 17 may be larger than a combined width of at least one of the flexible printed circuit board, the projecting part 53, the first protrusion part 51a, and the second protrusion part 51b. Accordingly, since the structure of the first protrusion part 51a, the second protrusion part 51b, and the projecting part 53 is disposed to be away from the sliding space of the flexible printed circuit board, the sliding movement inside the accommodation region 17 may not be disturbed when the flexible printed circuit board slides. Also, even when the sliding space of the flexible printed circuit board 41 is provided with the first protrusion part 51a and the second protrusion part 51b, or is changed by the stopper structure 55, the size and the structure of the product may not affected beyond a reference threshold.

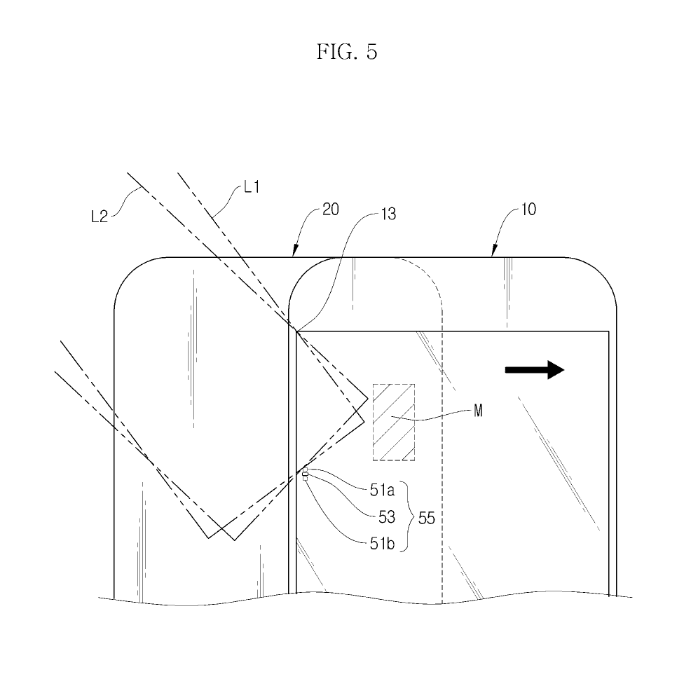

FIG. 5 is a schematic plan view illustrating a state where a card is inserted into a slide type mobile device according to an exemplary embodiment of the present invention.

Referring to FIG. 5, in the first body 10, the path through which the C-shaped curved part 43 of the flexible printed circuit board passes in FIG. 4A and FIG. 4B may be expressed as a region M. More specifically, when the sheet-like foreign material, such as paper or a card, is inserted into a gap between the first body 10 and the second body 20 and advances to the region M, the flexible printed circuit board may become damaged by the sheet-like foreign material.

However, according to exemplary embodiments of the present invention, the first protrusion part 51a, the second protrusion part 51b, and the projecting part 53 engage with each other to form the stopper structure 55, which may serves as a blockade or an obstruction to stop or impede the intrusion towards the region M by the sheet-like foreign material.

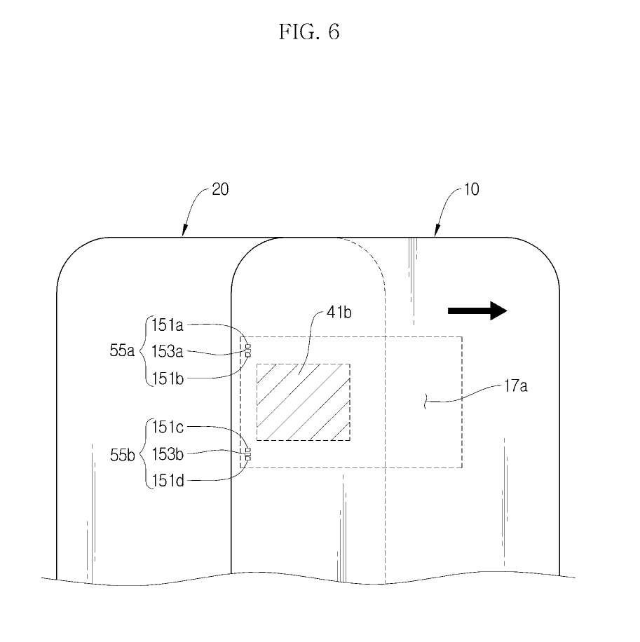

The sheet-like foreign material, such as a card, which may attempt to intrude into the mobile device to contact the flexible printed circuit board, may intrude at various angles. Referring to FIG. 5, the angles of entry may include a start angle corresponding to a first line L1 to be a start point, and an ending angle corresponding to a second line L2 to be an end point. The first line L1 may correspond to an insertion angle of the start point in which the sheet-like foreign material is inserted. The insertion angle is illustrated with respect an end portion 13 of the hinge member, which may be set as the start point in which the sheet-like foreign material may be inserted. The second line L2 may correspond to an insertion angle of the end point in which the stopper structure 55 obtained by the first protrusion part 51a, the second protrusion part 51b, and the projecting part 53 blocks the insertion path of the sheet-like foreign material. However, since increase of intruding angles with respect to a vertical axis may increase a likelihood of error that may be caused by the intrusion of the foreign material, additional protrusion parts and/or protruding parts may additionally be disposed at various areas, including an upper portion of the accommodation region 17 as shown in FIG. 6.

Accordingly, the card or the sheet-like foreign material, which may intrude from an outside of the end portion 13 of the hinge member, may be blocked or impeded by the stopper structure 55. More specifically, the insertion angle of the card or the sheet-like foreign material may be adjusted in accordance with a position and a gap disposed between the card insertion start point and the card insertion end point. As the insertion angle decreases with respect to the vertical axis, the frequency in which the card intrudes between the first body and the second body may decrease.

More specifically, as the gap between the end portion 13, which may be connected to the first hinge member and second hinge member, and the stopper structure 55 increases, the insertion angle with respect to the vertical axis may increase. However, since the stopper structure 55 may be formed or disposed so that the card insertion path does not contact the region M corresponding to the movement path of the C-shaped curved part, the insertion angle and the insertion path may be restricted.

When the stopper structure 55, or the first protrusion part 51a and the second protrusion part 51b are arranged according to the above-described method, the insertion angle and the insertion path of a card or foreign substance may be restricted, such that the card or the foreign substance does not contact the printed circuit board.

More particularly, when the sheet-like foreign material is inserted toward a concave portion of the C-shaped curved part 43, the sheet-like foreign material may approach the concave portion of the C-shaped curved part 43 so that the flexible printed circuit board may not move anymore and may become damaged or torn. Accordingly, as described above, the first protrusion part 51a, the second protrusion part 51b, or the stopper structure 55 may be disposed at a front portion of the concave portion of the C-shaped curved part 43.

According to exemplary embodiments of the present invention, the first protrusion part 51a, the second protrusion part 51b, and the projecting part 53 are arranged at one side of the sliding direction, indicated by the arrow, in which the card or other foreign material may be inserted in front of the concave part of the C-shaped curved part 43.

When the flexible component is disposed adjacent to an end portion of the mobile device, as described above, the end portion and the protrusion part 53 or the stopper structure 55 may form an insertion start point and an insertion end point, to prevent or reduce a likelihood of the intrusion of the sheet-like foreign material into the mobile device.

However, when the flexible component is disposed at a central region of the mobile device, the gap between a protrusion part or a stopper structure, and an end portion of the hinge member may increase, such that the insertion angle may increase over a reference threshold. Accordingly, intrusion of a sheet-like foreign material may not be effectively blocked or impeded.

Accordingly, the protrusion part and the projecting part, which may form the stopper structure, may be formed or disposed at both sides in a direction in which the foreign material is inserted. More specifically, the protrusion part and the projecting part may be disposed in front of the concave part of the C-shaped curved part 43 with respect to a sliding direction, which may be indicated by the arrow, in the accommodation region 17. Accordingly, the flexible component, which may be disposed at a central region of the mobile device, may be prevented from being damaged or may be less likely to be damaged by the intrusion of a foreign material.

More specifically, a likelihood of insertion of the sheet-like foreign material may be reduced or prevented by disposing the protrusion part or the stopper structure at a side where the card may be inserted, such as in front of the concave part of the C-shaped curved part 43, in a slide direction. In addition, the card insertion path or the card insertion angle may be adjusted by disposing the protrusion part or the stopper structure at a side surface of the flexible printed circuit board sliding path or path of movement.

FIG. 6 is a schematic diagram illustrating a slide type mobile device in an opened state according to an exemplary embodiment of the present invention.

Referring to FIG. 6, a first stopper structure 55a and a second stopper structure 55b are arranged. Further, a first protrusion part 151a, a second protrusion part 151b, a third protrusion part 151c, and a fourth protrusion part 151d are included in the first stopper structure 55a and the second stopper structure 55b. More specifically, the first stopper structure 55a includes the first protrusion part 151a and the second protrusion part 151b, and the second stopper structure 55b includes the third protrusion part 151c and the fourth protrusion part 151d.

Referring to FIG. 6, an accommodation region 17a is aligned with or provides a sliding path or a path of movement of the flexible printed circuit board, and the first stopper structure 55a and the second stopper structure 55b are formed or disposed at both a first side and a second side of the accommodation region 17a towards an edge in which a foreign material may be inserted according to a slide direction indicated by the arrow.

The first stopper structure 55a and the second stopper structure 55b are formed or arranged at both the first side and the second side of the accommodation region 17a near a starting point of the sliding direction as indicated by the arrow within a reference proximity to the flexible printed circuit board. More specifically, the first stopper structure 55a and the second stopper structure 55b may be formed or arranged at both the first side and the second side toward a concave part of the C-shaped curved portion of the flexible printed circuit board, thereby preventing or reducing a likelihood of intrusion of a foreign material, such as a card or paper.

The insertion angle and the insertion width may be adjusted by adjusting an insertion start point and an insertion end portion through an adjustment of a distance between the first stopper structure 55a and the second stopper structure 55b. Accordingly, a likelihood of intrusion of the foreign material, such as a card or paper, may be prevented or reduced using an appropriate arrangement according to a design of the product.

When a foreign material, such as a card or paper, is inserted into the gap formed or disposed between the first body 10 and the second body 20 towards a convex part of the C-shaped curved part 43, there may be a decreased possibility that the flexible printed circuit board may be pushed by the card or the paper to be damaged or torn.

However, the flexible printed circuit board may be protected from being damaged by disposing the protrusion parts or the stopper structures to be adjacent to the C-shaped curved part 43. More particularly, the protrusion parts or the stopper structures may be disposed at the rear side of the C-shaped curved part 43 in order to provide a more stable structure.

Further, the protrusion parts or the stopper structures may be formed or arranged in a middle region of the accommodation region 17 to cross the sliding path or the path of movement of the printed circuit board. Accordingly, it may be possible to prevent or reduce a likelihood of a foreign material, such as a card, from intruding into the concave part and/or the convex part of the C-shaped curved part 43 of FIG. 2B.

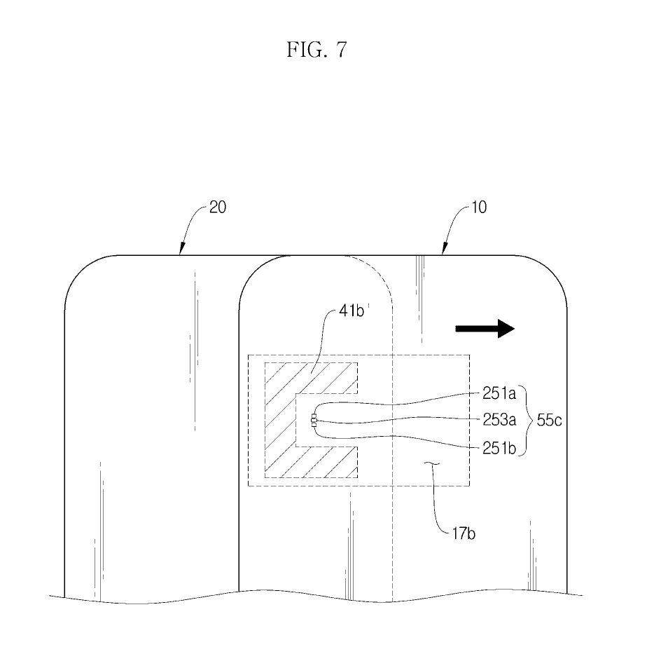

FIG. 7 is a schematic diagram illustrating a slide type mobile device in an opened state according to an exemplary embodiment of the present invention.

FIG. 7 is a diagram illustrating a state where a stopper structure 55c is formed or arranged in a middle region of an accommodation region 17b. Referring to FIG. 7, the stopper structure 55c may be disposed or arranged in the middle region of the accommodation region 17b, but is not limited thereto. For example, the stopper structure 55c may be formed or arranged at an interior or a central region of an accommodation region. The stopper structure 55c includes a first protrusion part 251a, a second protrusion part 251b, and a protruding part 253a. For example, the intrusion of the foreign material, such as a card, may be blocked or impeded just by forming the first protrusion part 251a and the second protrusion part 251b. Further, the stopper structure may be formed or arranged in multiples and/or at various locations of an accommodation region included in the mobile device.

The stopper structure 55c may be formed or disposed in the middle portion of the accommodation region 17 to cross the sliding path or the path of movement of the flexible printed circuit board. A flexible printed circuit part 41b′ of the flexible printed circuit board may be a separation type flexible printed circuit board. A stopper structure 55c may be formed or disposed in the separated portion to cross the flexible printed circuit part 41b′ of the flexible printed circuit board.

The first protrusion part 251a and the second protrusion part 251b may be formed or disposed in a middle region of the movement path of the flexible printed circuit board. The projecting part 253a may be formed or disposed to engage with the first protrusion part 251a and the second protrusion part 251b in the opened state. When the stopper structure 55c is formed or disposed in the middle region of the flexible printed circuit board, the foreign material, such as a card or the paper, which may be inserted towards a concave part or the convex part of the C-shaped curved part, may be blocked or impeded. Accordingly, the foreign material, such as a card or the paper, which may intrude from various paths, may be blocked or impeded by the stopper structure 55c.

However, aspects of the invention are not limited thereto. For example, the intrusion of a foreign material, which may be inserted from the outside may be prevented by forming one or more of protrusion parts and/or projecting parts at strategic positions in consideration of at least one of an exposed part of the flexible printed circuit board, the sliding path or the path of movement of the flexible printed circuit board, strokes or motions of a first body and a second body with respect to each other, a connection direction of the flexible printed circuit board, and the like.

Further, in the slide type mobile device in which the first body and the second body may move with a predetermined stroke or motion, it may be possible to prevent or reduce a likelihood of a flexible component disposed between the first body and the second body from becoming damaged by an intrusion of a foreign substance, such as a sheet-like foreign material.

More specifically, it may be possible to provide a slide type mobile device in which a stopper structure or a protrusion part may be disposed at various locations of the accommodation region to provide the sliding path or path of movement of the data connection line, such as the flexible printed circuit board electrically connecting the first body and the second body to each other. Accordingly, it may be possible to provide the slide type mobile device capable of preventing or reducing a probability that an insertion of a foreign material, such as a card or a sheet-like foreign material, may damage the sliding mechanism. Such slide type mobile device may be provided without changing the structure or the size of the mobile device.

Furthermore, since the insertion of the foreign material, such as paper or a card may be less likely, it may be possible to prevent or reduce a likelihood of degradation in the lifetime of the product, which may be associated with the flexible component being torn or damaged due to the foreign material intruding from the outside when the mobile device is in an opened state or a closed state. Accordingly, it may be possible to provide the mobile device capable of preventing or reducing a likelihood incurring unexpected damage associated with an insertion of foreign materials into the mobile device.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A mobile device, comprising:
a first body and a second body connected by a hinge member to provide a sliding movement of the first body with respect to the second body; and
a protrusion part disposed on one of the first body and the second body to extend toward the other of the first body and the second body.

2. The mobile device of claim 1, further comprising:
a projecting part disposed on one of the first body and the second body to extend toward the other of the first body and the second body.

3. The mobile device of claim 2, wherein the projecting part is disposed within a reference proximity of a first end portion of the first body.

4. The mobile device of claim 1, wherein the protrusion part is disposed within a reference proximity of a second end portion of the first body.

5. The mobile device of claim 1, wherein the protrusion part is disposed in an interior region of a surface of one of the first body and the second body.

6. The mobile device of claim 2, wherein the protrusion part and the projecting part are arranged to form a stopping structure when the first body is in an opened state with respect to the second body.

7. The mobile device of claim 2, wherein the protrusion part and the projecting part are arranged to at least partially overlap one another when the first body is in an opened state with respect to the second body.

8. The mobile device of claim 2, wherein the protrusion part and the projecting part are arranged in parallel.

9. The mobile device of claim 1, wherein the hinge member comprises:
a first hinge attached to the first body; and
a second hinge attached to the second body.

10. The mobile device of claim 9, further comprising:
a flexible printed circuit board connected between the first body with the second body.

11. The mobile device of claim 10, further comprising:
a recessed portion disposed on the first body or the second body to provide a path of movement of the flexible printed circuit board.

12. The mobile device of claim 11, wherein the protrusion part is disposed within the path of movement of the flexible printed circuit board.

13. The mobile device of claim 11, wherein the protrusion part is disposed adjacent to the path of movement of the flexible printed circuit board.

14. The mobile device of claim 11, wherein a width of the recessed portion is larger than or equal to a combined width of the flexible printed circuit board and at least one of the protrusion part and a projecting part.

15. The mobile device of claim 11, wherein the protrusion part is disposed to cross the path of movement of the flexible printed circuit board.

16. The mobile device of claim 1, wherein a surface of the first body faces a surface of the protrusion part.

17. The mobile device of claim 1, wherein a height of the protrusion part is smaller than a distance between a surface of the first body and a surface of the second body, the surface of the first body facing the surface of the second body.

18. The mobile device of claim 1, wherein a surface of the first body faces a surface of the second body.

19. The mobile device of claim 1, wherein the protrusion part is disposed to face a concave portion of the flexible printed circuit board.

20. A mobile device, comprising:
a first body and a second body connected by a hinge member to provide a sliding movement;
a projecting part disposed on the first body to extend towards the second body; and
a protrusion part disposed on the second body to extend towards the first body,
wherein the protrusion part and the projecting part are arranged to form a stopper structure when the first body is in an opened state with respect to the second body.

21. A slide type mobile device, comprising:
a first body and a second body connected by a hinge member to move in a sliding motion with respect to one another;
a flexible printed circuit board disposed to extend between the first body and the second body;
a first protrusion part disposed at a first side on a surface of the second body within a reference proximity of the flexible printed circuit board; and
a second protrusion part disposed at a second side on the surface of the second body within a reference proximity of the flexible printed circuit board.
